(19) United States
(12) Patent Application Publication
(10) Pub. No.: US 2017/0275762 A1
(43) Pub. Date: Sep. 28, 2017

(54) POLYGON DEPOSITION SOURCES WITH HIGH MATERIALS UTILIZATION AND INCREASED TIME BETWEEN CHAMBER CLEANINGS

(71) Applicant: ASCEN TOOL INC

(72) Inventor: George Xinsheng Guo, Palo Alto, CA (US)

(73) Assignee: ASCEN TOOL INC

(21) Appl. No.: 14/882,401

(22) Filed: Oct. 13, 2015

(51) Int. Cl. C23C 16/54; C23C 14/34; C23C 14/35; H01J 37/32

(52) U.S. Cl. CPC C23C 16/54; H01J 37/3244; H01J 37/32743; C23C 14/3407; C23C 14/35; C23C 14/3464

(57) ABSTRACT

The present application discloses a new type of deposition source, where individual sources are placed in a substantial closed loop. The closed polygon deposition sources have no end in circumference and enable better deposition uniformity. A closed loop deposition sources minimize the edge effects in sputtering, chemical vapor deposition (CVD) and plasma enhanced chemical vapor deposition (PECVD) and increase deposition material utilization.

### PRIORITY CLAIM

This application is a non-provisional utility patent application that claims the benefit of U.S. Provisional Patent Application No. 62/063,806, entitled “polygon deposition sources with high materials utilization and increased time between chamber cleanings”, which was filed on Oct. 14, 2014, all of which are incorporated by reference herein in its entirety.

### BACKGROUND

The present application relates to material deposition technologies, and more specifically to high throughput deposition apparatus.

Material deposition in vacuum is widely used in photovoltaic cells and panels, window glass coating, flat panel display manufacturing, coating on flexible films (such as webs), hard disk coating, industrial surface coating, semiconductor wafer processing, and other applications.

The present invention describes a deposition system that increases material utilization, increase the time between cleaning of the deposition chamber, and reduce particulates.

### SUMMARY OF THE INVENTION

The present application discloses a new type of deposition source, where individual sources are placed in a substantial closed loop. The closed polygon deposition sources have no end in circumference and enable better deposition uniformity. A closed loop deposition sources minimize the edge effects in sputtering, chemical vapor deposition (CVD) and plasma enhanced chemical vapor deposition (PECVD) and increase deposition material utilization. In case of plasma enhanced deposition such as sputtering deposition and plasma enhanced chemical vapor deposition (PECVD), a closed loop deposition sources allow electrons to travel in a closed loop with the aid of magnetic field and substantially increase operating plasma density and reduce operating pressure. A magnetic field by a specifically designed electrical coil or permanent magnets can enhance plasma density, improves plasma uniformity and decrease operating pressure for sputtering, PECVD, or etching of the substrates. Electrons drift under Lawrence force and electrode voltage and form a close loop over the polygon surfaces. The plasma uniformity is better than conventional planar magnetrons where electrons have to form a closed loop over the same planar source.

Planar sputtering targets are the lowest cost target. PECVD showerhead is planar in general. Individual deposition sources can be placed close to each other and forms a substantially closed loop around the substrate carries. Each deposition source can be substantially planar to decrease cost. The deposition sources can be sputtering sources, sputtering targets, CVD or PECVD sources, heaters, or gas distribution. In some cases, the individual deposition sources can be replaced by a one or more integrated deposition sources, reducing the number of sources and system cost.

When a permanent magnet loop is scanned behind the target surface, it provides a uniform target material consumption in most area except two ends of the target that do not touch other targets and increase target utilization. The permanent magnet loop can be scanned over the target surfaces to achieve uniform erosion and increase the target material utilization.

To improve the material utilization at the two ends, the targets and its cooled backing plates can be made in three sections, where the middle section is large and has uniform erosion and the end sections have a tapered erosion profile. After certain use, most likely after the middle section materials are used up and needs to be replaced, the end sections are either switched or turned to opposite direction to use up rest of the materials on the end target sections. Alternatively, an electrical coil provides the magnetic field, electron travel in a loop and forms uniform plasma. This uniform plasma can improve sputtering target utilization or PECVD uniformity. The drop off in magnetic field strength also decreases the target utilization. A three sectioned target and applying a special designed switching method can improve material utilization. The three sections can have different target thickness to further optimize the material utilization rate. It is also possible that only the targets are made of three sections, while the backing plate is one piece. The targets are de-bonded from the backing plate after first use, switched and re-bonded to the backing plate after the new middle section target is replaced.

Shields are used to prevent deposition on the chamber walls and other parts. Shields are also placed next to the sputtering cathode to provide a positive bias to form plasma. When too much film thickness is deposited on the shield, the film may peel off and form particulates on substrates.

Another advantage of the deposition system is that the deposition source has only two ends, instead of four in conventional systems. This allows many benefits such as sputtering off materials deposited on anode shields, or sputter off the native oxide and contamination on shield surface before commencement of sputtering deposition to enhance the adhesion of the deposited film on the shield. This will reduce particulates formation and increase the time between chamber cleanings.

In some embodiments, the anode shield sits next to target. To sputter off the native oxide or the deposited film, the anode shield can be negatively biased relative to its surroundings, forming plasma between the anode shield and surrounding areas aided by magnetic field. The plasmas sputter the surfaces of the anode shield and remove materials. The removal of oxide and contamination prior to deposition improves the adhesion of the deposited materials on the shield and reduce particulate formation. Longer sputtering can also remove substantial or all deposited materials on the anode shield, decreasing the need to open chambers to manually clean or change the shield. This will enable higher productivity of the deposition system and reduce cost of cleaning. The bias can also be applied to another shield placed opposite to the anode shield while the anode shield is being cleaned. The bias can be switched to clean all shields. Dummy substrates can be loaded between the anode shield and the positively biased shield to accept the sputtered material from the anode shield, reducing materials deposited on the positively biased shields. The dummy substrates are later removed for reuse or for cleaning. A gap between dummy substrates allows the plasma to be formed. The electrical coil or the closed loop permanent magnets can be placed behind the anode shield to enhance the plasma. Scanning of the magnetic field over the surface of the anode shield can ensure completer removal of the deposited material or surface contamination on the anode shield. The scanning speed or/and sputter power can be varied to match the deposited film thickness distribution for complete removal of deposited material without taking off too much shield materials.

In the case of sputtering using scanning magnetron, there is only one magnet loop required. The sputtering erosion region can be wide by using wider magnet and has minimum impact on material utilization if a wide target is also used or a three section targets and switching method are used. The magnetic field strength can be quite strong and a much thicker target can be used compared with conventional planar or rotary targets. The thicker and wider target reduces the frequency to replace the target. Electrical magnets allow even thicker targets. Combined with sputter cleaning and material removal of the shields, the system down time due to target changes and shield changes is also greatly reduced. In addition, the maintenance labor and cost such as target bonding, recalibration and system qualification, system burn-in and wasted substrates are reduced.

Alternatively, a thin or normal thickness target will have strong magnetic field on the target surface, increase plasma density, reduce target voltage, and reduce plasma damages on substrate.

In PECVD, the targets are replaced by shower heads, where incoming process gases are fed to the gas distribution plate to minimize impact of flow differentials between inlet and more distant locations. The specifically designed electrical coil is optional and can increase plasma density and lower the operating pressure. One potential issue with this shower head design is that the gas coming out of the shower head starts to react and form films on the nearby surfaces or form particulates in the gas phase before it reaches the substrate, lowering the material utilization. The present application places gas distribution near the substrates to reduce the loss of gas to reactions and improves material utilization. In general the gas distribution should be closer to the substrate than the shower head. Since the substrates are moving against the gas distribution in a constant speed, non-uniformity is minimized. In the case that the gas distribution is made of small surface area tubes, it reduces the available surface area that can accumulate film deposition, further increasing material utilization. Another advantage is the distribution tubes have fewer holes than the shower head, reducing cost since no hole is needed on the shower head in some applications. If two or more separate gases are used in the deposition source, gas from both shower head and gas distribution plate are separated until them reaches the reaction chamber and reduce the reactions between these gases in the gas distribution pipelines. The openings in the gas distribution line can point down; point down at an angle or sideways relative to the substrates to increase the deposition efficiency.

In some embodiments, a sputtering source enabling high material utilization comprises a central target comprising a first end and a second end, wherein the central target has a uniform erosion profile; a first one end target positioned next to the first end of the central target, wherein the first end target has a tapered erosion profile that is characterized by a target thickness increase with an increase in distance away from the central target; and a back plate on which the central target and the first end target are mounted, wherein the back plate includes a mounting mechanism that enables the first end target to be removed after a period of sputtering, and re-mounted in an opposite orientation such that the tapered erosion profile is characterized by a target thickness decrease with an increase in distance away from the central target.

In some embodiments, the mounting mechanism is realized when a target is mounted to a backing plate by a low melting temperature material such as Indium, or high temperature conductive polymer, or explosion bonding. In some embodiments, the mounting mechanism is realized by mechanical clamping that can secure a target is place while allowing the target to be removed when a mechanical switch is turned off. In some embodiments, the mounting mechanism is realized by electrostatic attraction that can secure a target in place while allowing the target to be removed by shutting off an electrical switch.

In some embodiments, a closed loop deposition source is used in the current application and invention. In some embodiments, a sputtering system that can enable high material utilization, comprises one or more deposition sources that form a first substantially closed loop, wherein the one or more deposition sources comprise sputtering targets that are distributed in a second substantially closed loop; one or more back plates on which the one or more sputtering targets are mounted, wherein the one or more back plates include mounting mechanisms that enable the one or more sputtering targets to be removed after a period of sputtering. In some embodiments, the one or more deposition sources comprise magnets that are distributed in a third substantially closed loop.

In some embodiments, a deposition system comprises: one or more deposition sources that form a first substantially closed loop, wherein the one or more deposition sources comprise gas distribution systems that are distributed in a second substantially closed loop, wherein the one or more deposition sources comprise magnets that are distributed in a third substantially closed loop. In some embodiments, the one or more deposition sources are configured to produce vapor for chemical vapor deposition (CVD) or plasma enhanced chemical vapor deposition (PECVD).

### BRIEF DESCRIPTION OF THE DRAWINGS

FIGS. 1A-1C illustrate exemplified detailed configurations of deposition sources, substrates, and processing chamber compatible with the disclosed high throughput deposition apparatus.

FIG. 1D shows an example of the cross section of a sputtering source using permanent magnets.

FIG. 1E shows an example of the cross section of a sputtering source where the initial target condition before use on top, after first use, after installing a new middle section and switched end sections, and after second use are illustrated.

FIGS. 2A-2B illustrate exemplified detailed configurations of a sputtering source with the anode shield next to target.

FIG. 3A-3C illustrate exemplified detailed configurations of a sputtering source with specifically designed gas distribution and cooling components and shower head.

FIG. 4 illustrate an example of a method to use a sputtering source efficiently.

### DETAILED DESCRIPTION OF THE INVENTION

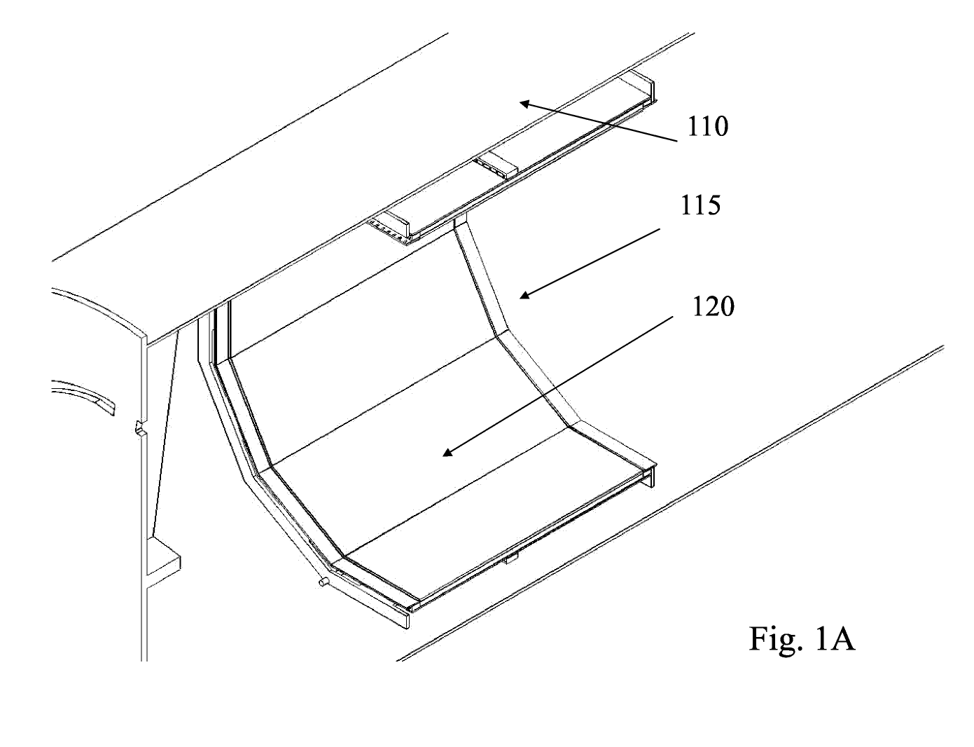

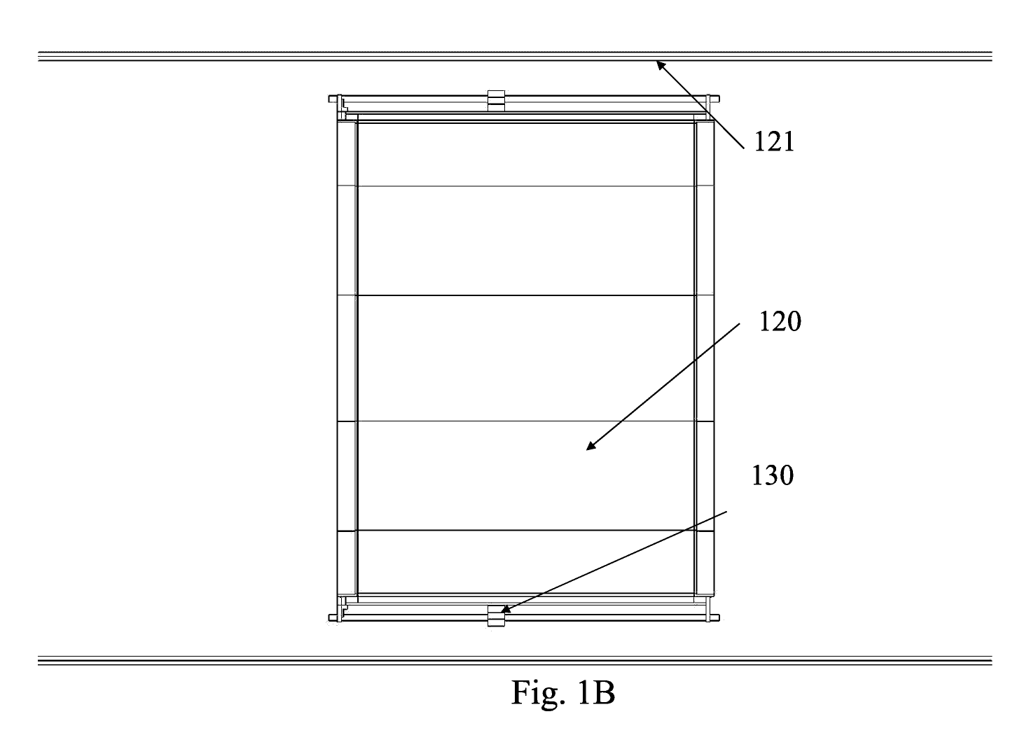

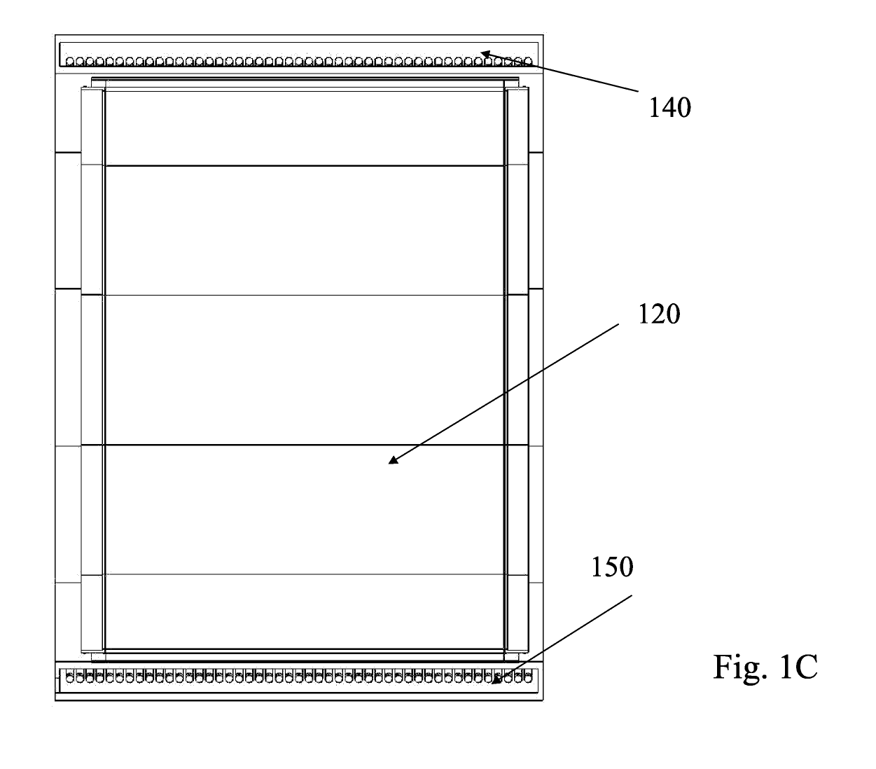

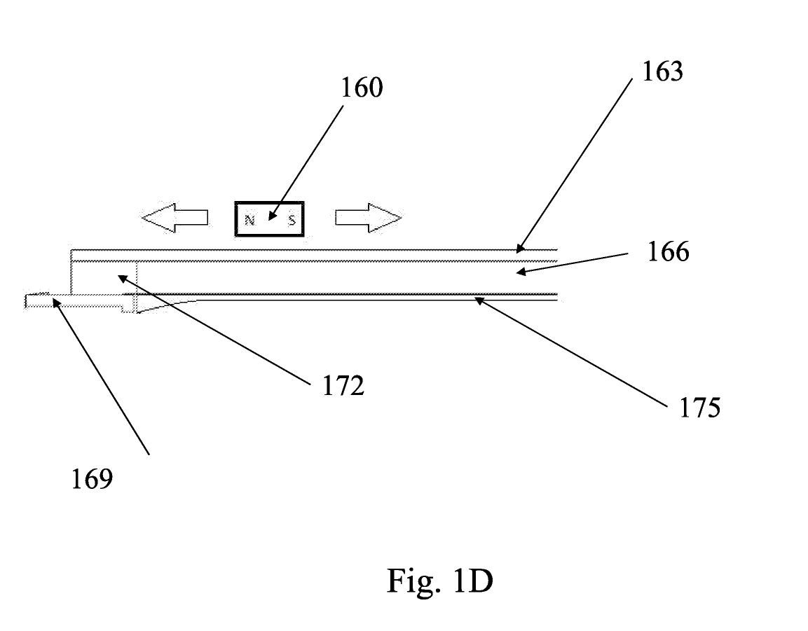

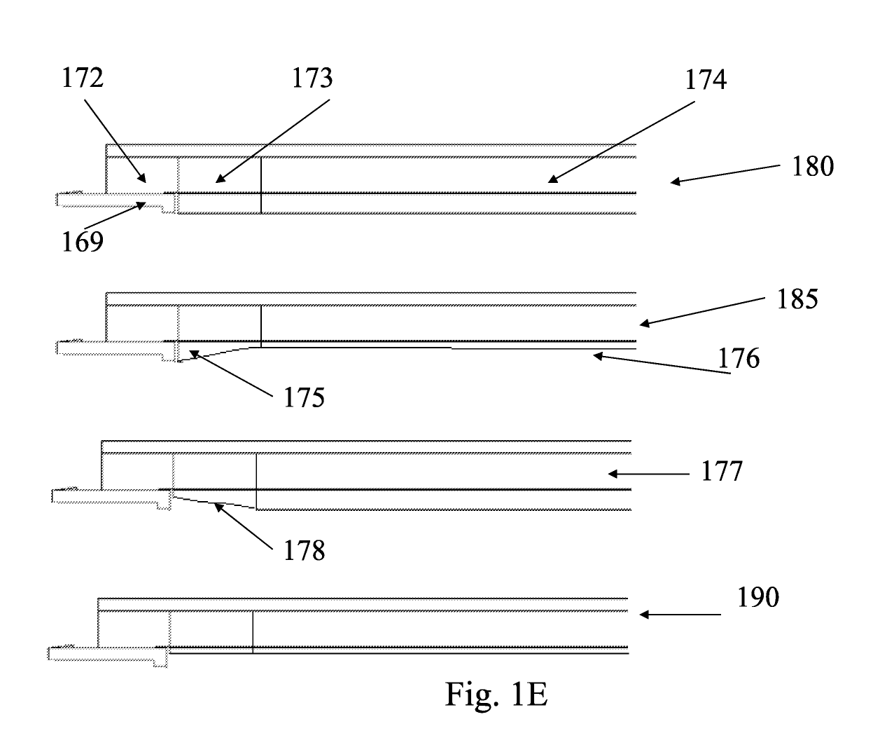

FIG. 1A illustrate one embodiment of exemplified detailed configurations of deposition sources, substrates, and processing chamber compatible with the disclosed high throughput deposition apparatus. In some embodiments, in a process chamber 110, multiple deposition sources 120 can be placed close to each other to form a substantially closed loop 115 around substrates mounted on a main carrier (not shown). Each deposition source can be substantially planar to decrease cost. The deposition sources 120 can be sputtering sources, sputtering targets, CVD or PECVD sources, heaters, or gas distribution. In some cases, the individual deposition sources 120 can be replaced by one or more integrated deposition sources, reducing the number of sources and system cost.

A magnetic field by either electrical coil or permanent magnets can enhance plasma density, improves plasma uniformity and decrease operating pressure for sputtering, PECVD, or etching of the substrates. Electrons drift under Lawrence force and electrode voltage or target voltage and form a close loop over the polygon surfaces. The plasma uniformity is better than conventional planar magnetrons where electrons have to form a closed loop over the same planar source. In an alternative setup, individual conventional sputtering sources with closed loop magnetic field formed over same planar source or other individual deposition sources can also form a substantial closed loop or partial closed loop to achieve at least partial benefits of the present invention.

Referring to FIG. 1B, inside of process chamber wall 121, a permanent magnet loop 130 is scanned behind the deposition sources 120, it provides a uniform magnetic field around target surfaces, and uniform target material consumption in most target areas, which increases target utilization.

Alternatively, referring to FIG. 1C, an electrical coil 140 provides the magnetic field, electrons travel in a loop and form uniform plasma near the surfaces of the deposition sources 120. This uniform plasma can improve sputtering target utilization or PECVD uniformity. The magnetic flux is substantially parallel to the target or shower head surface, and a large plasma area is formed. The reduced plasma heating per unit area can allow higher deposition rate and reduced target temperature in sputtering. In some embodiments, a cooling container 150 is used to cool the electrical coil 140 inside the deposition chamber 110.

FIG. 1D shows the cross section of a sputtering source using permanent magnets. A permanent magnet loop 160 can be scanned over the target surfaces to achieve uniform erosion and increase the target material utilization. A back insulator 163 is coupled to a backing plate 166. A eroded target 175 is coupled to the backing plate 166. An insulator 172 is coupled between the back insulator 163 and an anode shield 169.

FIG. 1E shows the initial target condition before use on top, after first use, after installing a new middle section and switched end sections, and after second use where the erosion is substantially uniform on the bottom of the figure. To improve the material utilization at the two ends, the eroded target 175 and the cooled backing plate 166 can be made in three sections, where the middle section is large and has uniform erosion and the end sections have a tapered erosion profile. After certain use, most likely after the middle section materials are used up and needs to be replaced, the end sections are either switched or turned to opposite direction to use up rest of the materials on the end target sections. For example, in the situation of before use 180, a side insulator 172 is coupled between the anode shield 169 and backing plate end section 173. A back plate middle section 174 is coupled to the backing plate end section 173. After the first use 185, a new middle section is added and end target is switched to be the switched end target 178. Therefore, at the 2^{nd} use 190, the material utilization at the two ends is improved. For larger targets, the middle section and end section can be made of multiple target pieces due to limited size of targets that can be manufactured.

An additional benefit is the edge sections can act as the seal to the cooling channels drilled into the middle section of the backing plate, reducing complexity and cost of the backing plate.

Alternatively, an electrical coil provides the magnetic field, electron travel in a loop and forms uniform plasma. This uniform plasma can improve sputtering target utilization or PECVD uniformity. The drop off in magnetic field strength also decreases the target utilization. A three sectioned target and applying the switching method illustrated in FIG. 1E can improve material utilization.

Shields are used to prevent deposition on the chamber walls and other parts. Shields are also place next to the sputtering cathode to provide a positive bias to form plasma. When too much film thickness is deposited on the shield, the film may peel off and form particulates on substrates.

Another advantage of the deposition system is that the deposition source has only two ends, instead of four in conventional systems. This allows many benefits such as sputtering off materials deposited on anode shields, or sputter off the native oxide and contamination on shield surface before commencement of sputtering deposition to enhance the adhesion of the deposited film on the shield. This will reduce particulates formation and increase the time between chamber cleanings.

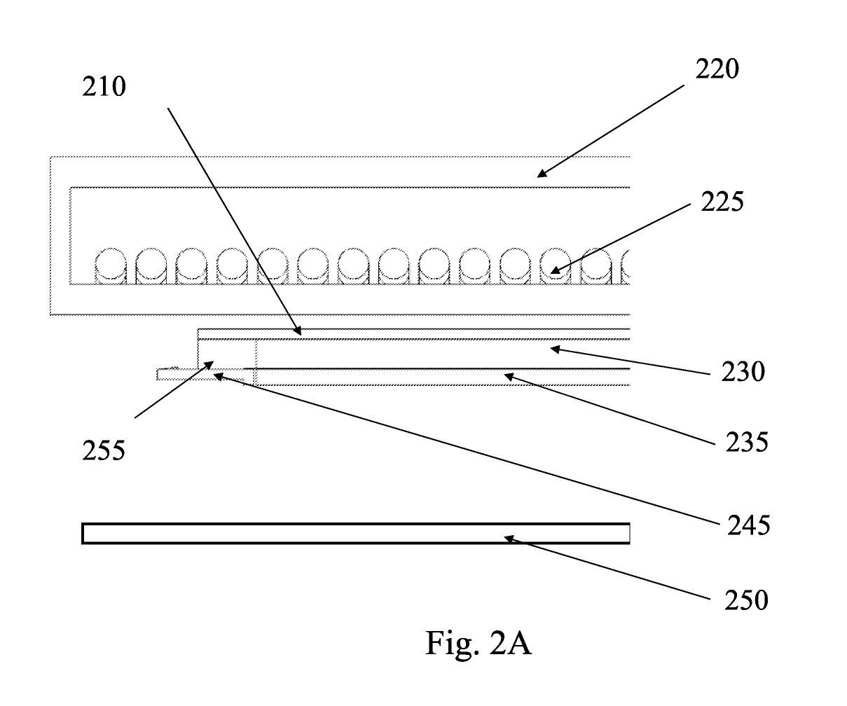

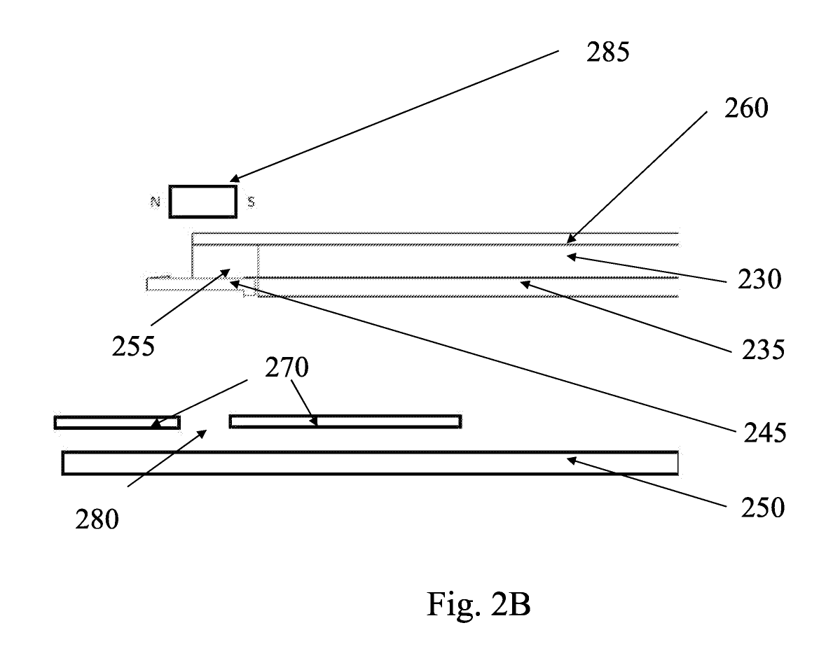

FIGS. 2A-2B illustrate exemplified detailed configurations of a sputtering source with the anode shield next to target. In FIG. 2A, the conducting coils 225 are coupled to the cooling container 220. The back insulator 210 is coupled to the backing plate 230. The backing plate is coupled to the target 235. The anode shield 245 is coupled to an insulator 255 that is coupled to a backing plate 230. The anode shield 245 can be negatively biased relative to the target 235, the shield 250, or both. A grounded or positively biased shield 250 is placed under insulator 255. In FIG. 2B, the permanent magnet loop 285 is placed above the back insulator 260 and the backing plate 230. The backing plate 230 is coupled to the target 235. The anode shield 245 is coupled to an insulator 255 that is coupled to a backing plate 230. A grounded or positively biased shield 250 is placed under insulator 255. In between the insulator 255 and the positively biased shield 250, there are dummy substrates 270. Between the dummy substrates 270, there is a gap 280 to allow plasma formation.

To sputter off the native oxide or the deposited film, the anode shield 245 can be negatively biased relative to its surroundings, forming plasma between the anode shield and surrounding areas aided by magnetic field. The plasmas sputter the surfaces of the anode shield 245 and remove materials. The removal of oxide and contamination prior to deposition improves the adhesion of the deposited materials on the shield and reduce particulate formation. Longer sputtering can also remove substantial or all deposited materials on the anode shield, decreasing the need to open chambers to manually clean or change the shield. This will enable higher productivity of the deposition system and reduce cost of cleaning. The bias can also be applied to another shield placed opposite to the anode shield while the anode shield is being cleaned. The bias can be switched to clean all shields. Dummy substrates can be loaded between the anode shield and the positively biased shield to accept the sputtered material from the anode shield, reducing materials deposited on the positively biased shields. The dummy substrates are later removed for reuse or for cleaning. A gap between dummy substrates allows the plasma to be formed. The electrical coil or the closed loop permanent magnets can be placed behind the anode shield to enhance the plasma. Scanning of the magnetic field over the surface of the anode shield can ensure completer removal of the deposited material or surface contamination on the anode shield. The scanning speed or/and sputter power can be varied to match the deposited film thickness distribution for complete removal of deposited material without taking off too much shield materials.

In the case of sputtering using scanning magnetron, there is only one magnet loop required. The sputtering erosion region can be wide by using wider magnet and has minimum impact on material utilization if a wide target is also used or a three section targets and switching method are used. The magnetic field strength can be quite strong and a much thicker target can be used compared with conventional planar or rotary targets. The thicker and wider target reduces the frequency to replace the target. Electrical magnets allow even thicker targets. Combined with sputter cleaning and material removal of the shields, the system down time due to target changes and shield changes is also greatly reduced. In addition, the maintenance labor and cost such as target bonding, recalibration and system qualification, system burn-in and wasted substrates are reduced.

Alternatively, a thin or normal thickness target will have strong magnetic field on the target surface, increase plasma density, reduce target voltage, and reduce plasma damages on substrate.

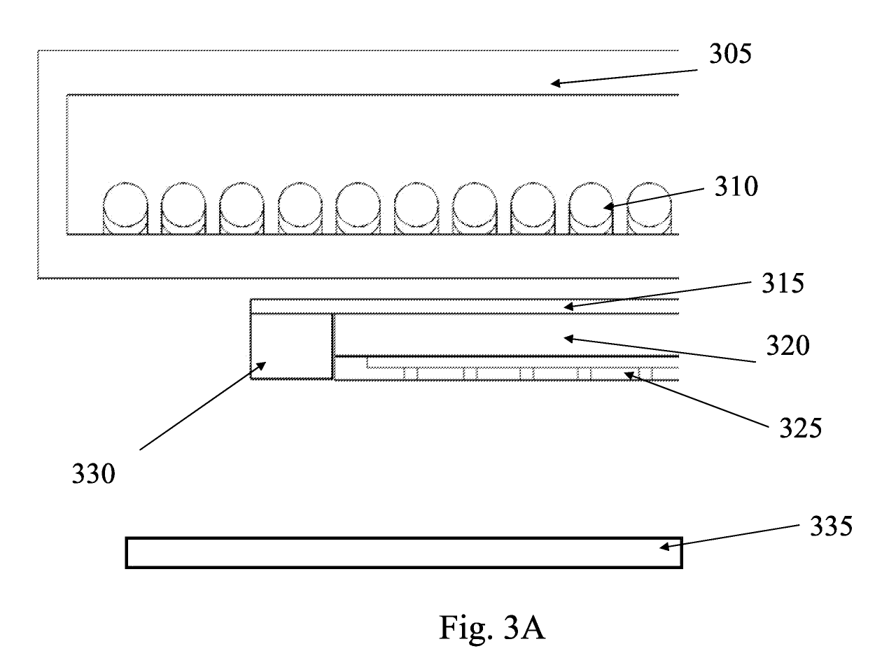

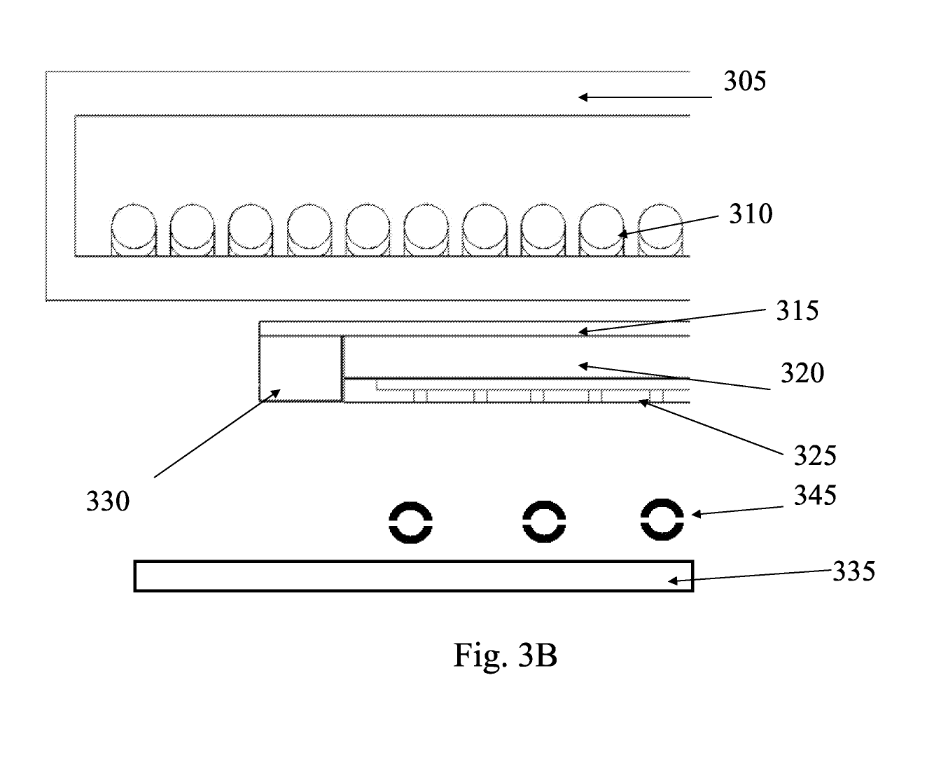

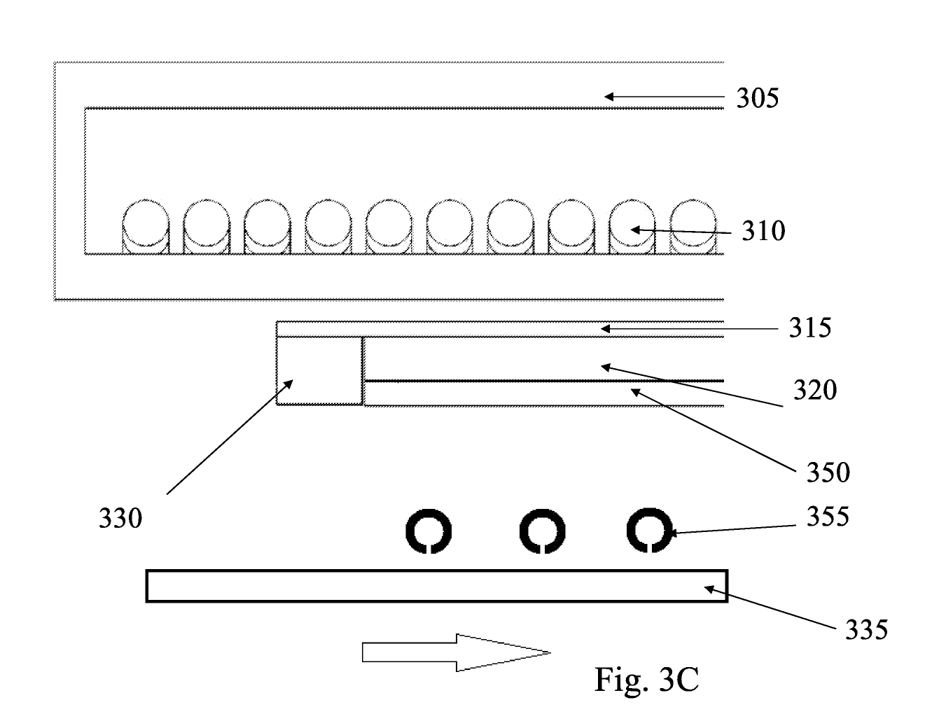

FIG. 3A-3C illustrate exemplified detailed configurations of a deposition source with specifically designed gas distribution and cooling components and shower head. In FIG. 3A, the configuration of the deposition system comprises a cooling container 305, a conducting coil 310, a back insulator 315, a gas distribution and cooling system 320, shower head 325, insulator 330 and substrate 335. In FIG. 3B, the configuration of the deposition system comprises a cooling container 305, a conducting coil 310, a back insulator 315, a gas distribution and cooling 320, shower head 325, insulator 330, substrate 335 and gas distribution components 345. The gas distribution components 345 are located near to the substrate 335 and the distance between the gas distribution components 345 and the substrate is between 1% to 50%, or more commonly 10% to 30% of the distance between the shower head 325 or electrodes to the substrate 335. The gas distribution components 345 release gas in a horizontal direction. In FIG. 3C, the configuration of the sputtering system comprises a cooling container 305, a conducting coil 310, a back insulator 315, a gas distribution and cooling 320, shower head 325, insulator 330, substrate 335 and gas distribution components 345. The gas distribution components 345 are located near to the substrate 335 and the distance between the gas distribution components 345 and the substrate is between 10% to 30% of the distance between the shower head 325 to the substrate 335. The gas distribution components 345 release gas to the substrate. In some embodiments, the shower heads are replaced by electrodes to improve performances.

In PECVD, the targets are replaced by shower heads as shown in FIG. 3A, where incoming process gases are fed to the gas distribution plate to minimize impact of flow differentials between inlet and more distant locations. The electrical coil shown in FIG. 2A is optional and can increase plasma density and lower the operating pressure. One potential issue with this shower head design is that the gas coming out of the shower head starts to react and form films on the nearby surfaces or form particulates in the gas phase before it reaches the substrate, lowering the material utilization. The present invention places gas distribution near the substrates to reduce the loss of gas to reactions and improves material utilization, as shown in FIG. 3B. In general the gas distribution should be closer to the substrate than the shower head. Since the substrates are moving against the gas distribution in a constant speed, non-uniformity is minimized. In the case that the gas distribution is made of small surface area tubes, it reduces the available surface area that can accumulate film deposition, further increasing material utilization. Another advantage is the distribution tubes have fewer holes than the shower head, reducing cost since no hole is needed on the shower head in some applications, as shown in FIG. 3C. If two or more separate gases are used in the deposition source, gas from both shower head and gas distribution plate are separated until them reaches the reaction chamber and reduce the reactions between these gases in the gas distribution pipelines, as illustrated in FIG. 3B. Electrical coil is used in the illustration; permanent magnets can also be used to enhance plasma density. The openings in the gas distribution line can point down; point down at an angle or sideways relative to the substrates to increase the deposition efficiency. The polygon shaped deposition sources include rectangular sources where there can be multiple closed loop rectangular sources in the same process chamber. This can increase the number of substrate that can be processed at a time.

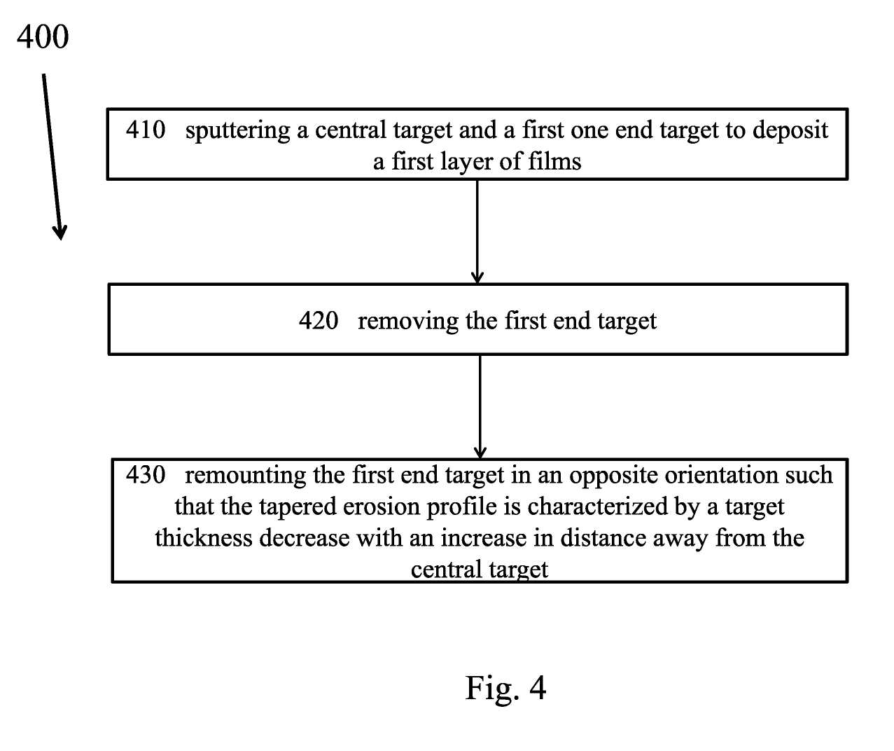

FIG. 4 illustrates an example of a method 400 to use a sputtering source efficiently. At step 410, a central target and a first one end target were sputtered. The central target comprises a first end and a second end and the central target has a uniform erosion profile. The first one end target is positioned next to the first end of the central target and the first end target has a tapered erosion profile that is characterized by a target thickness increase with an increase in distance away from the central target.

In some embodiments, at step 420 the first end target is removed. In some embodiments, at step 430, the first end target is remounted in an opposite orientation such that the tapered erosion profile is characterized by a target thickness decrease with an increase in distance away from the central target. In some embodiments, a sputtering target is mounted to a backing plate by a low melting temperature material such as Indium, or high temperature conductive polymer, or explosion bonding.

In some embodiments, the mounting mechanism is realized when a target is mounted to a backing plate by a low melting temperature material such as Indium, or high temperature conductive polymer, or explosion bonding. In some embodiments, the mounting mechanism is realized by mechanical clamping that can secure a target is place while allowing the target to be removed when a mechanical switch is turned off. In some embodiments, the mounting mechanism is realized by electrostatic attraction that can secure a target in place while allowing the target to be removed by shutting off an electrical switch.

What is claimed is:

1. A sputtering source enabling high material utilization, comprising:
a central target comprising a first end and a second end, wherein the central target has a uniform erosion profile;
a first one end target positioned next to the first end of the central target, wherein the first one end target has a tapered erosion profile that is characterized by a target thickness increase with an increase in distance away from the central target; and
a backing plate on which the central target and the first one end target are mounted, wherein the backing plate includes a mounting mechanism that enables the first one end target to be removed after a period of sputtering, and re-mounted in an opposite orientation such that the tapered erosion profile is characterized by a target thickness decrease with an increase in distance away from the central target.

2. The efficient sputtering source of claim 1, further comprising:
a side insulator coupled to the backing plate.

3. The efficient sputtering source of claim 2, further comprising:
an anode shield coupled to the side insulator.

4. The efficient sputtering source of claim 1, wherein the efficient sputtering source is a closed loop deposition source.

5. A method to use a sputtering source efficiently, comprising:
sputtering a central target and a first one end target, wherein a central target comprising a first end and a second end, wherein the central target has a uniform erosion profile, wherein the first one end target positioned next to the first end of the central target, wherein the first one end target has a tapered erosion profile that is characterized by a target thickness increase with an increase in distance away from the central target;
removing the first one end target; and
remounting the first one end target in an opposite orientation such that the tapered erosion profile is characterized by a target thickness decrease with an increase in distance away from the central target.

6. A sputtering source with high productivity, comprising:
one or more anode shields, wherein the one or more anode shield are negatively biased relative to surroundings of the one or more anode shields, wherein plasma is formed between the one or more anode shields, wherein the plasma is configured to sputter surfaces of the one or more anode shields to remove oxide and contaminations on the one or more anode shields; and
a magnet system is placed behind the one or more anode shield, wherein placements of the magnet system are configured to enhance the plasma, wherein scanning of magnetic field generated by the magnet system over surface of the one or more anode shield is configured to remove deposited material or surface contamination on the one or more anode shield.

7. A sputtering source with high productivity of claim 6, wherein the magnet system comprises one magnets loop or one or more electrical coils.

8. The sputtering source with high productivity of claim 7, further comprising:
one or more dummy substrates placed between one or more anode shields and another shield, wherein the one or more anode shield is negatively biased relative to surroundings, wherein the one or more dummy substrates are configured to accept the sputtered material from the one or more anode shield, reducing materials deposited on the another shield.

9. The sputtering source with high productivity of claim 7, wherein scanning speed magnetic field generated by the permanent magnet loops or the electrical coils or sputter power can be varied to match deposited film thickness distribution for removal of deposited material one or more anode shields without taking off too much shield materials.

10. A deposition system, comprising:
one or more electrodes coupled to one or more insulators and cooling plates;
and
one or more gas tubes coupled to gas supplies, wherein the one or more gas tubes are closer to a substrate than the one or more electrodes; and
one or more electrodes form a substantially closed loop.

11. The deposition system of claim 10, further comprising:
a magnet system coupled to the one or more electrodes, wherein the magnet system are configured to increase plasma density and lower operating pressure.

12. The deposition system of claim 11, wherein the magnet system comprises one or more electrical coils or permanent magnets.

13. The deposition system of claim 11, wherein openings in the one or more gas tubes are configured to point down relative to the substrates to increase the deposition efficiency.

14. The deposition system of claim 11, wherein openings in the one or more gas tubes are configured to point down at an angle relative to the substrates to increase the deposition efficiency.

15. The deposition system of claim 11, wherein openings in the one or more gas tubes are configured to point sideway relative to the substrates to increase the deposition efficiency.

16. The deposition system of claim 11, wherein distance between the one or more gas tubes and the substrate is ranging from 10% to 30% of distance between the sputtering target and the substrate.

17. A sputtering system enabling high material utilization, comprising:
one or more deposition sources that form a first substantially closed loop, wherein the one or more deposition sources comprise sputtering targets that are distributed in a second substantially closed loop;
one or more back plates on which the one or more sputtering targets are mounted, wherein the one or more back plates include mounting mechanisms that enable the one or more sputtering targets to be removed after a period of sputtering.

18. The sputtering system enabling high material utilization of claim 17, wherein the one or more deposition sources comprise magnets that are distributed in a third substantially closed loop.

19. A deposition system, comprising:
one or more deposition sources that form a first substantially closed loop, wherein the one or more deposition sources comprise gas distribution systems that are distributed in a second substantially closed loop, wherein the one or more deposition sources comprise magnets that are distributed in a third substantially closed loop.

20. The deposition system of claim 19, wherein the one or more deposition sources are configured to produce vapor for chemical vapor deposition (CVD) or plasma enhanced chemical vapor deposition (PECVD).

21. A sputtering source enabling high material utilization, comprising:
a central target mounted to a backing plate comprising a first end and a second end, wherein the central target has a uniform erosion profile;
a first one end target mounted to a backing plate positioned next to the first end of the central target, wherein the first one end target has a tapered erosion profile that is characterized by a target thickness increase with an increase in distance away from the central target; and
the first one end target mounted on backing plate to be removed after a period of sputtering, and re-mounted in an opposite orientation such that the tapered erosion profile is characterized by a target thickness decrease with an increase in distance away from the central target.

22. The efficient sputtering source of claim 21, further comprising:
a side insulator coupled to the backing plate.

23. The efficient sputtering source of claim 21, further comprising:
an anode shield coupled to the side insulator.

24. The efficient sputtering source of claim 21, wherein the efficient sputtering source is a closed loop deposition source.
